(19) United States
(12) Patent Application Publication
(10) Pub. No.: US 2013/0247822 A1
(43) Pub. Date: Sep. 26, 2013

(54) DEPOSITION APPARATUS

(71) Applicant: ASM IP HOLDING B.V., Almere (NL)

(72) Inventors: Hyun-Kyu CHO, Daejeon (KR); Dong Rak JUNG, Cheonan-si (KR); Dae-Youn KIM, Daejeon (KR)

(73) Assignee: ASM IP Holding B.V., Almere (NL)

(21) Appl. No.: 13/803,486

(22) Filed: Mar. 14, 2013

(30) Foreign Application Priority Data
Mar. 23, 2012 (KR) 10-2012-0030180

(51) Int. Cl. C23C 16/458

(52) U.S. Cl. CPC C23C 16/458
USPC 118/500

(57) ABSTRACT

In a deposition apparatus, a protecting member made of an elastic body is inserted into a pin hole where a fixed substrate supporting pin is inserted and the substrate supporting pin is fixed through the protecting member to prevent damages to the substrate and a decrease in yield due to damages to the substrate supporting pin by preventing the substrate supporting pin from being damaged by loading or unloading of the substrate or static electricity. Further, the deposition apparatus includes a substrate supporting pin guide member capable of preventing misalignment of an unfixed substrate supporting pin to prevent damages to the substrate and a decrease in the yield due to damages to the substrate supporting pin by preventing the substrate supporting pin from being damaged by loading or unloading of the substrate or static electricity.

### CROSS-REFERENCE TO RELATED APPLICATION

This application claims priority to and the benefit of Korean Patent Application No. 10-2012-0030180 filed in the Korean Intellectual Property Office on Mar. 23, 2012, the entire contents of which are incorporated herein by reference.

### BACKGROUND OF THE INVENTION

(a) Field of the Invention

The present invention relates to a deposition apparatus.

(b) Description of the Related Art

In a deposition apparatus which deposits a film on a silicon substrate, when the substrate is loaded before processing or unloaded after processing, a substrate supporting pin or substrate lift pin is used.

The substrate supporting pin includes a fixed supporting pin and an unfixed supporting pin. The fixed supporting pin fixes a lower portion of the substrate supporting pin to a pin hole of a lift pin supporter. When the fixed supporting pin is used, the substrate supporting pin may be damaged by friction at the inside of the pin hole.

When the unfixed substrate supporting pin is used, the substrate supporting pin moves vertically at the time the substrate is loaded or unloaded. Further, when the substrate supporting pin moves vertically, the substrate supporting pin may be caught in a substrate lift pin hole and damaged.

As such, when the supporting pin is damaged, the substrate is not accurately loaded or unloaded. As a result, the substrate may be damaged. Further, when the substrate is not loaded at an accurate position, processing gas permeates into a rear side of the substrate, resulting in deposition of an unnecessary thin film or generation of contaminated particles in a reactor.

In a deposition process using plasma, static electricity may be generated on the substrate where the thin film is deposited. If the substrate is moved after the processing, the substrate supporting pin sticks to the rear side of the substrate due to the static electricity, thus, obstructing the movement of the substrate or damaging the substrate supporting pin or the substrate.

In order to solve the above identified problems, Korean Patent Publication No. 10-2006-0068132 discloses a method of discharging static electricity through a lower plate supporting the substrate supporting pin by gold-plating the substrate supporting pin. Further, Korean Patent Publication No. 10-2007-0008975 discloses a method of preventing damage to a substrate or a supporting pin by inserting a metal rod into the substrate supporting pin to discharge static electricity generated during processing through a lift hoop supporting the supporting pin.

However, even if the structures described in the above identified publication are used, when an unnecessary thin film, such as an oxide thin film, is formed between the supporting pin and the plate or lift hoop supporting the supporting pin while the process is repeated several times, discharging of the static electricity itself is not performed.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a deposition apparatus having advantages of reducing damage to a substrate supporting pin when a substrate is loaded or unloaded by using the substrate supporting pin, and preventing a substrate supporting pin from deviating from a means supporting the substrate supporting pin to prevent the substrate supporting pin or the substrate from being damaged, although static electricity is generated during a plasma process.

An exemplary embodiment of the present invention provides a deposition apparatus, including: a substrate supporter; a substrate supporting pin inserted into a hole formed in the substrate supporter; a supporting plate supporting the substrate supporting pin, in which the substrate supporting pin is inserted into the hole formed in the supporting plate; and a protecting member disposed between the substrate supporting pin and the hole and sticking into the hole.

The protecting member may surround a lower end of the substrate supporting pin. The protecting member may include an elastic body. In addition, or alternatively, the protecting member may include a spring.

Another exemplary embodiment of the present invention provides a deposition apparatus, including: a substrate supporter; a substrate supporting pin inserted into a hole formed in the substrate supporter; a supporting plate supporting the substrate supporting pin; a guide ring sticking to the lower portion of the substrate supporting pin; and a guide plate sticking to the supporting plate, in which the guide ring and the guide plate are spaced apart from each other at a predetermined distance.

The guide plate may be overlapped with at least a part of the guide ring. The guide ring and the guide plate may be spaced apart from each other at about 2 mm to about 10 mm. The guide plate may be overlapped with the entire guide ring.

According to the exemplary embodiments of the present invention, a protecting member made of an elastic body is inserted into a pin hole into which a fixed substrate supporting pin is inserted and the substrate supporting pin is fixed through the protecting member. Therefore, it is possible to prevent damages to the substrate and a decrease in yield due to damages to the substrate supporting pin by preventing the substrate supporting pin from being damaged by loading or unloading of the substrate or static electricity.

Further, according to the exemplary embodiments of the present invention, the deposition apparatus includes a substrate supporting pin guide member capable of preventing misalignment of an unfixed substrate supporting pin, and as a result, it is possible to prevent damages to the substrate and a decrease in the yield due to damages to the substrate supporting pin by preventing the substrate supporting pin from being damaged by loading or unloading of the substrate or static electricity.

### BRIEF DESCRIPTION OF THE DRAWINGS

FIG. 1 is a cross-sectional view illustrating a deposition apparatus according to an exemplary embodiment of the present invention.

FIG. 2 is a cross-sectional view illustrating a part of the deposition apparatus according to an exemplary embodiment of the present invention.

FIG. 3 is a diagram illustrating a protecting member of a substrate supporting pin according to an exemplary embodiment of the present invention.

FIG. 4 is a diagram schematically illustrating an operation of the part of the deposition apparatus according to an exemplary embodiment of the present invention.

FIG. 5A is a diagram illustrating a part of a deposition apparatus according to another exemplary embodiment of the present invention.

FIG. 5B is a cross-sectional view illustrating a part of the deposition apparatus illustrated in FIG. 5A.

FIG. 6A is a diagram illustrating a part of a deposition apparatus according to yet another exemplary embodiment of the present invention.

FIG. 6B is a cross-sectional view illustrating a part of the deposition apparatus illustrated in FIG. 6A.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

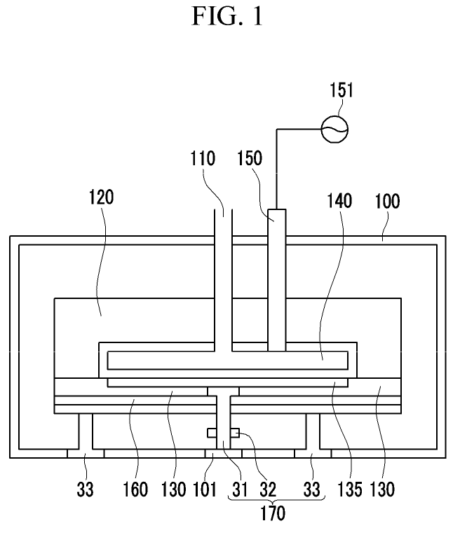

First, a deposition apparatus according to an exemplary embodiment of the present invention will be described with reference to FIG. 1. FIG. 1 is a cross-sectional view illustrating a deposition apparatus according to an exemplary embodiment of the present invention.

Referring to FIG. 1, the deposition apparatus includes an outer wall 100, a gas passage pipe 110, a chamber wall 120, a substrate supporter 130, a chamber plate 140 defining a reaction space together with the substrate supporter 130, a high-frequency connection terminal 150 for transferring high-frequency power to the chamber plate 140 in order to induce plasma in the chamber, and a high-frequency power supply 151 connected to the high-frequency connection terminal 150.

The respective constituent elements will be described in more detail as follows.

A substrate 135 which is an object to deposit a film is disposed on the substrate supporter 130, and a heating plate 160 is disposed below the substrate supporter 130. The heating plate 160 serves to increase the temperature of the substrate up to a temperature required for a process, and may be omitted.

In order to load or unload the substrate, a substrate supporter driver 170 for driving the substrate supporter 130 includes a substrate supporting pin 31 which is inserted into a hole formed in the substrate supporter 130 to support the substrate, and a vertical driver 33 controlling a vertical movement of the substrate supporter 130. As the vertical driver 33, various means controlling the vertical movement of the substrate supporter 130, such as a pneumatic cylinder, may be used. The substrate supporting pin 31 may be supported by a supporting plate 101 formed at the lower portion of the deposition apparatus.

Now, the vertical movement of the substrate supporter 130 for loading or unloading the substrate will be described. Before and after a deposition process, the substrate supporter 130 and the heating plate 160 connected to the vertical driver 33 move downwards and the chamber wall 120 and the substrate supporter 130 are separated from each other to open the chamber. As a result, the substrate 135 may be loaded in the chamber or unloaded to the outside. In this case, if the substrate supporting pin 31 is an unfixed type, the substrate supporting pin 31 moves up or down by the vertical movement of the supporting plate 101, and thus, the substrate 135 may be unloaded from the substrate supporter 130 or loaded on the substrate supporter 130.

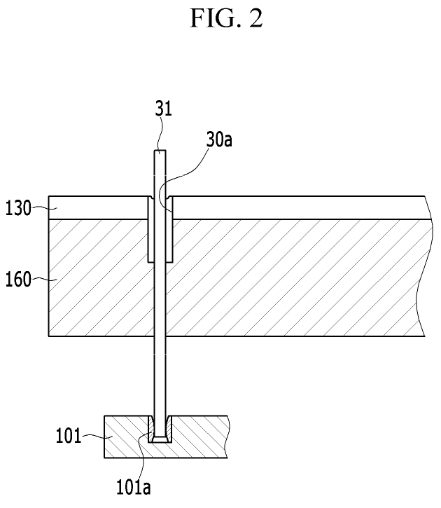

The substrate supporting pin 31 and the supporting plate 101 supporting the substrate supporting pin 31 of the deposition apparatus according to exemplary embodiments of the present invention will be described with reference to FIGS. 2 to 4.

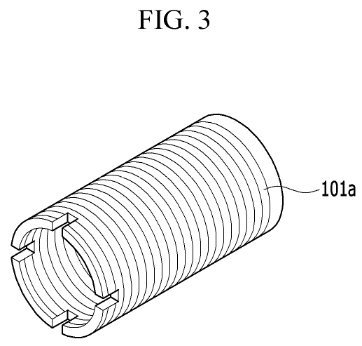

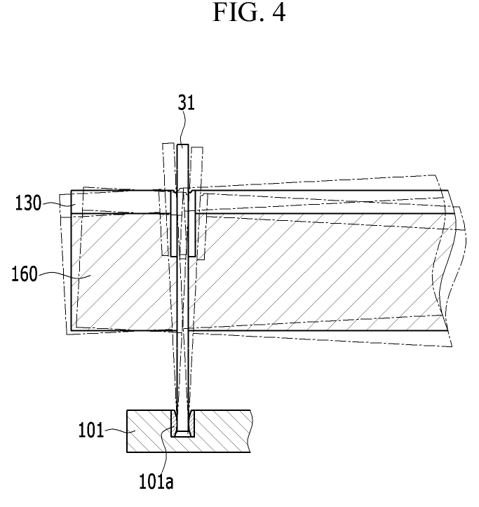

FIG. 2 is a cross-sectional view illustrating a part of the deposition apparatus according to an exemplary embodiment of the present invention, and FIG. 3 is a diagram illustrating an example of a protecting member of a substrate supporting pin. FIG. 4 is a diagram schematically illustrating an operation of the part of the deposition apparatus according to an exemplary embodiment of the present invention.

Referring to FIG. 2, the substrate supporting pin 31, which is inserted into the substrate supporter 130 and the heating plate 160, passes through a supporting pin inserter 30a formed in the substrate supporter 130 and the heating plate 160 to be inserted and fixed in a pin hole formed in the supporting plate 101. A substrate supporting pin protecting member 101a is formed in the pin hole formed in the supporting plate 101 of the deposition apparatus according to an exemplary embodiment of the present invention, and the substrate supporting pin 31 is inserted into the pin hole through the substrate supporting pin protecting member 101a.

The substrate supporting pin protecting member 101a may include an elastic body. Accordingly, even if the substrate supporting pin 31 moves horizontally, the substrate supporting pin 31 may not be damaged and may be restored to an original position. Referring to FIG. 3, the substrate supporting pin protecting member 101a may be a plate spring.

Referring back to FIG. 1, when the substrate supporter 130 and the heating plate 160 move vertically, the substrate supporter 130 and the heating plate 160 may move horizontally. As a result, the substrate supporting pin 31 fixed in the supporting plate 101 is easily damaged due to friction with the supporting pin inserter 30a. However, in the case of the deposition apparatus, as illustrated in FIG. 4, the substrate supporting pin 31 is protected by elasticity of the substrate supporting pin protecting member 101a formed in the pin hole of the supporting plate 101, thereby preventing the substrate supporting pin 31 from being damaged due to the movement of the substrate supporter 130 and the heating plate 160. Further, even if the substrate supporting pin 31 and the substrate 135 stick to each other and move together by static electricity accumulated on the substrate 135 after the deposition process, the substrate supporting pin 31 is protected by the substrate supporting pin protecting member 101a formed in the pin hole of the supporting plate 101, thereby preventing the substrate supporting pin 31 from being damaged.

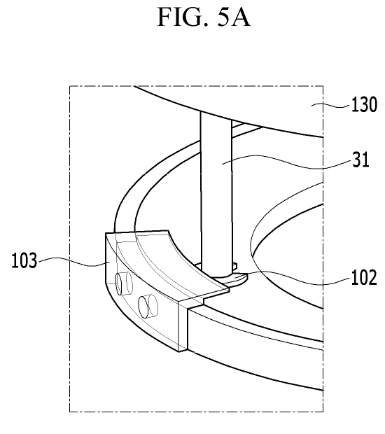

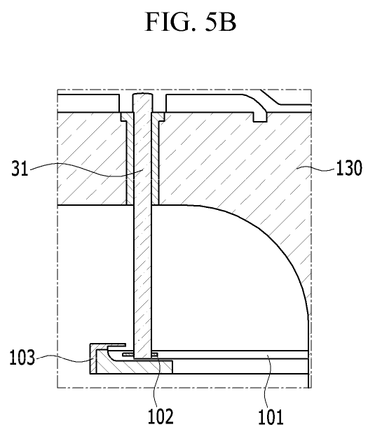

Then, the substrate supporting pin 31 and the supporting plate 101 supporting the substrate supporting pin 31 of the deposition apparatus according to an exemplary embodiment of the present invention will be described with reference to FIGS. 5A and 5B. FIG. 5A is a diagram illustrating a part of a deposition apparatus according to another exemplary embodiment of the present invention, and FIG. 5B is a cross-sectional view illustrating a part of the deposition apparatus illustrated in FIG. 5A.

Referring to FIGS. 5A and 5B, the substrate supporting pin 31 of the deposition apparatus, which is an unfixed type, is supported by the supporting plate 101 and protected by a supporting pin guide member. The supporting pin guide member includes a supporting pin guide ring 102 sticking to the lower portion of the substrate supporting pin 31, and a supporting pin guide plate 103 sticking to the supporting plate 101 and that is spaced apart from the supporting pin guide ring 102 in a vertical direction. The supporting pin guide plate 103 is disposed to be vertically overlapped with a part of the supporting pin guide ring 102.

The supporting pin guide ring 102 and the supporting pin guide plate 103 are disposed to maintain a vertical distance of about 2 mm to about 10 mm.

When the substrate is loaded or unloaded, the supporting plate 101 supporting the substrate supporting pin 31 moves vertically, and thus, the substrate supporting pin 31 moves vertically. Even in this case, the substrate supporting pin 31 is inserted into the substrate supporter 130 through the supporting pin inserter formed at the substrate supporter 130. When the substrate supporting pin 31 moves vertically, friction with the supporting pin inserter in the substrate supporter 130 is generated, and as a result, sticking in the supporting pin inserter occurs, and thus, the substrate supporting pin 31 may be damaged.

However, as illustrated in FIGS. 5A and 5B, when the substrate supporting pin 31 sticks into the supporting pin inserter such that the vertical movement is not smooth, as the supporting plate 101 moves, the supporting pin guide plate 103 sticking to the supporting plate 101 moves together with the supporting plate 101. After the supporting pin guide plate 103 contacts the supporting pin guide ring 102 sticking to the lower portion of the substrate supporting pin 31, the substrate supporting pin 31 physically moves vertically together with the supporting pin guide ring 102, thereby preventing damage to the substrate supporting pin 31 which may be resulted when the substrate supporting pin 31 sticks in the supporting pin inserter and does not move.

Further, even if the substrate supporting pin 31 and the substrate 135 stick to each other by static electricity accumulated on the substrate 135 after the deposition process, and thus, the supporting plate 101 moves, the substrate supporting pin 31 does not move. Even in this case, as the supporting plate 101 moves, the supporting pin guide plate 103 sticking to the supporting plate 101 moves together. After the supporting pin guide plate 103 contacts the supporting pin guide ring 102 sticking to the lower portion of the substrate supporting pin 31, the substrate supporting pin 31 physically moves together with the supporting pin guide ring 102, thereby preventing the substrate supporting pin 31 from being damaged due to sticking.

Many features of the deposition apparatus according to the exemplary embodiment described above may all be applied to the deposition apparatus.

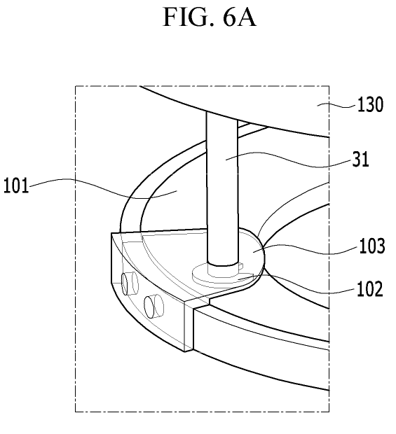

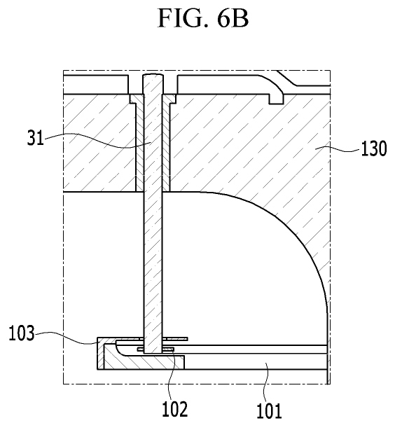

The substrate supporting pin 31 and the supporting plate 101 supporting the substrate supporting pin 31 of a deposition apparatus according to yet another exemplary embodiment of the present invention will be described with reference to FIGS. 6A and 6B. FIG. 6A is a diagram illustrating a part of a deposition apparatus according to yet another exemplary embodiment of the present invention, and FIG. 6B is a cross-sectional view illustrating a part of the deposition apparatus illustrated in FIG. 6A.

The deposition apparatus described referring to FIGS. 6A and 6B is similar to the deposition apparatus illustrated in FIGS. 5A and 5B. Referring to FIGS. 6A and 6B, the substrate supporting pin 31 of the deposition apparatus is an unfixed type, supported by the supporting plate 101 and protected by a supporting pin guide member. The supporting pin guide member includes a supporting pin guide ring 102 sticking to the lower portion of the substrate supporting pin 31, and a supporting pin guide plate 103 sticking to the supporting plate 101 and that is spaced apart from the supporting pin guide ring 102 in a vertical direction. The supporting pin guide ring 102 and the supporting pin guide plate 103 are disposed to maintain a vertical distance of about 2 mm to about 10 mm.

However, unlike the deposition apparatus according to the exemplary embodiment illustrated in FIGS. 5A and 5B, in the deposition apparatus exemplified in FIGS. 6A and 6B, the supporting pin guide plate 103 of the supporting pin guide member surrounds the substrate supporting pin 31. That is, the substrate supporting pin 31 is inserted into the supporting pin guide plate 103. The supporting pin guide plate 103 is formed to be vertically overlapped with the entire supporting pin guide ring 102. Accordingly, when the supporting plate 101 moves, but the substrate supporting pin 31 does not move, the supporting pin guide plate 103 physically moves the substrate supporting pin 31 by contacting the entire supporting pin guide ring 102 surrounding the substrate supporting pin 31, and thus, may move more effectively.

Like the deposition apparatus according to the exemplary embodiment described above, when the substrate supporting pin 31 sticks into the supporting pin inserter and does not move, as the supporting plate 101 moves, the supporting pin guide plate 103 sticking to the supporting plate 101 moves together with the supporting plate 101. After the supporting pin guide plate 103 contacts the supporting pin guide ring 102 sticking to the lower portion of the substrate supporting pin 31, the substrate supporting pin 31 physically moves vertically together with the supporting pin guide ring 102, thereby preventing damages to the substrate supporting pin 31 which may be resulted when the substrate supporting pin 31 sticks into the supporting pin inserter and does not move smoothly.

Further, the substrate supporting pin 31 and the substrate 135 can stick to each other by static electricity accumulated on the substrate 135 after the deposition process, and thus, the supporting plate 101 moves, but the substrate supporting pin 31 does not move. In this case, as the supporting plate 101 moves, the supporting pin guide plate 103 sticking to the supporting plate 101 moves together, and the supporting pin guide plate 103 contacts the supporting pin guide ring 102 sticking to the lower portion of the substrate supporting pin 31 so that the substrate supporting pin 31 physically moves together with the supporting pin guide ring 102, thereby preventing the substrate supporting pin 31 from being damaged due to sticking.

Many features of the deposition apparatus according to the exemplary embodiments described above may all be applied to the deposition apparatus.

The shapes and layouts of the substrate supporting pin, the substrate supporting pin protecting member, and the substrate supporting pin guide member of the deposition apparatus according to the exemplary embodiments described above are only the examples for describing the present invention, and the present invention is not limited thereto and may be modified in various forms.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus, comprising:
a substrate supporter;
a substrate supporting pin inserted into a hole formed in the substrate supporter;
a supporting plate supporting the substrate supporting pin, in which the substrate supporting pin is inserted into the hole formed in the supporting plate; and
a protecting member disposed between the substrate supporting pin and the hole, the protecting member sticking into the hole.

2. The deposition apparatus of claim 1, wherein:
the protecting member surrounds a lower end of the substrate supporting pin.

3. The deposition apparatus of claim 2, wherein:
the protecting member includes an elastic body.

4. The deposition apparatus of claim 3, wherein:
the protecting member includes a spring.

5. The deposition apparatus of claim 1, wherein:
the protecting member includes an elastic body.

6. The deposition apparatus of claim 5, wherein:
the protecting member further includes a spring.

7. A deposition apparatus, comprising:
a substrate supporter;
a substrate supporting pin inserted into a hole formed in the substrate supporter;
a supporting plate supporting the substrate supporting pin;
a guide ring sticking to a lower portion of the substrate supporting pin; and
a guide plate sticking to the supporting plate,
wherein the guide ring and the guide plate are spaced apart from each other at a predetermined distance.

8. The deposition apparatus of claim 7, wherein:
the guide plate is overlapped with at least a part of the guide ring.

9. The deposition apparatus of claim 8, wherein:
the guide ring and the guide plate are spaced apart from each other at about 2 mm to about 10 mm.

10. The deposition apparatus of claim 7, wherein:
the guide plate is overlapped with the entire guide ring.

11. The deposition apparatus of claim 10, wherein:
the guide ring and the guide plate are spaced apart from each other at about 2 mm to about 10 mm.

12. The deposition apparatus of claim 7, wherein:
the guide ring and the guide plate are spaced apart from each other at about 2 mm to about 10 mm.
